(19) United States
(12) Patent Application Publication
(10) Pub. No.: US 2026/0133244 A1
(43) Pub. Date: May 14, 2026

(54) SEMICONDUCTOR PACKAGE TEST DEVICE USING PELTIER ELEMENT

(71) Applicant: LIVINGCARE CO.,LTD., Daegu (KR)

(72) Inventors: Tage Ryul KWON, Daegu (KR); JunHyun PARK, Daegu (KR)

(21) Appl. No.: 19/488,752

(22) PCT Filed: Dec. 13, 2023
(86) PCT No.: PCT/KR2023/020509

§ 371 Date: Nov. 28, 2025

(30) Foreign Application Priority Data
Jan. 9, 2023 (KR) 10-2023-0002602

(51) Int. Cl. G01R 31/26; G01R 31/27

(52) U.S. Cl. CPC G01R 31/2642; G01R 31/27

(57) ABSTRACT

The present invention relates to a semiconductor package test device using a Peltier element, the device comprising a Peltier chamber unit in which a thermoelectric block located at a lower portion of a first Peltier block comprising a Peltier element comes into contact with an upper portion of a semiconductor package and changes the temperature of the upper portion of the semiconductor package, a socket guide that guides the semiconductor package and is located on a test board, and a pad part on an upper portion of which an electrical connection part coupled to an input/output terminal of a lower portion of the semiconductor package is provided, and which is located on the test board.

### TECHNICAL FIELD

The present invention relates to a device for testing a semiconductor package, specifically to a semiconductor package test device using Peltier elements that is capable of testing a semiconductor package according to changes in temperature and a method for adjusting a test temperature of a semiconductor package.

### BACKGROUND ART

A wafer contains hundreds of thousands of integrated circuit dies, after undergoing various semiconductor manufacturing processes, and the individual dies are isolated and then packaged, after their characteristics have been assessed. As a result, a semiconductor package for the die is made. The semiconductor package has to normally function in every environment. That is, the semiconductor package has to normally function at low or high temperature as well as at room temperature. However, some semiconductor packages do not function well or function abnormally at low or high temperature. In this case, they are sorted as defective products.

The semiconductor packages as defective products undergo defect analysis so that their defect reasons or positions are detected. To perform the defect analysis, in this case, the same environment when the defects occur on the semiconductor packages has to be given. To perform the test for the semiconductor packages, accordingly, there is a need to allow the areas adjacent to the semiconductor packages to heat up or cool down if necessary.

### DISCLOSURE

### Technical Problem

Accordingly, the present invention has been made in view of the above-mentioned problems occurring in the related art, and it is an object of the present invention to provide a semiconductor package test device using Peltier elements that is capable of allowing a semiconductor package as a test target to have generally uniform temperature to thus keep a low temperature difference between internal layers of the semiconductor package, which is because a temperature difference between the respective layers of the semiconductor package is not high in the case where the semiconductor package located in a final product is used in external environments.

### Technical Solution

To accomplish the above-mentioned object, according to the present invention, a semiconductor package test device using Peltier elements may include a Peltier chamber unit in which a thermoelectric block located on the underside of a first Peltier block constituted of the Peltier elements comes into contact with top of a semiconductor package to change a temperature on the top of the semiconductor package, socket guides located on a test board to guide the semiconductor package, and a pad part located on the test board and having electrical connectors coupled to input and output terminals on the underside of the semiconductor package.

The Peltier chamber unit may include: one or more temperature compensation modules located on one side and the other side of a lower portion thereof in such a way as to come into contact with a portion of the test board on the outsides of the socket guides, when the thermoelectric block is coupled with the semiconductor package, to change the temperature on the underside of the semiconductor package; and a first water cooling jacket located on top of the first Peltier block in such a way as to cool the first Peltier block.

The temperature compensation modules may include a first temperature compensation module fixed to one side of the lower portion of the Peltier chamber unit and a second temperature compensation module fixed to the other side of the lower portion of the Peltier chamber unit.

In this case, the first temperature compensation module and the second temperature compensation module may be located on the outsides of the socket guides, when brought into contact with the test board.

Further, the first temperature compensation module may include: a second Peltier block for emitting cool air or heat to the portion of the test board; a second water cooling jacket located on top of the second Peltier block to cool the second Peltier block; and a first heat transfer plate located on the underside of the second Peltier block in such a way as to come into contact with the portion of the test board.

Furthermore, the semiconductor package test device may further include a packing located between the Peltier chamber unit and the socket guides to seal the Peltier chamber unit and the socket guides.

Additionally, the semiconductor package test device using the Peltier elements may be configured to allow the top of the semiconductor package to have a temperature between −50 and 150° C. and to allow the interior of the semiconductor package to have a temperature between −40 and 125° C.

### Advantageous Effects of Invention

According to the embodiment of the present invention, the semiconductor package test device using the Peltier elements is configured to control temperatures on both sides coming into contact with the semiconductor package and thus minimize a temperature deviation between internal layers of the semiconductor package tested, thereby enhancing the reliability in the test.

### BRIEF DESCRIPTION OF DRAWINGS

FIG. 1 is a schematic sectional view showing a conventional semiconductor package test device.

FIG. 2 is a schematic sectional view showing a semiconductor package test device using Peltier elements according to an embodiment of the present invention.

### BEST MODE FOR INVENTION

To accomplish the above-mentioned object, according to the present invention, a semiconductor package test device using Peltier elements may include a Peltier chamber unit in which a thermoelectric block located on the underside of a first Peltier block constituted of the Peltier elements comes into contact with top of a semiconductor package to change a temperature on the top of the semiconductor package, socket guides located on a test board to guide the semiconductor package, and a pad part located on the test board and having electrical connectors coupled to input and output terminals on the underside of the semiconductor package.

The Peltier chamber unit may include: one or more temperature compensation modules located on one side and the other side of a lower portion thereof in such a way as to come into contact with the portion of the test board on the outsides of the socket guides, when the thermoelectric block is coupled with the semiconductor package, to change the temperature on the underside of the semiconductor package; and a first water cooling jacket located on top of the first Peltier block in such a way as to cool the first Peltier block.

The temperature compensation modules may include a first temperature compensation module fixed to one side of the lower portion of the Peltier chamber unit and a second temperature compensation module fixed to the other side of the lower portion of the Peltier chamber unit.

In this case, the first temperature compensation module and the second temperature compensation module may be located on the outsides of the socket guides, when brought into contact with the test board.

Further, the first temperature compensation module may include: a second Peltier block for emitting cool air or heat to the portion of the test board; a second water cooling jacket located on top of the second Peltier block to cool the second Peltier block; and a first heat transfer plate located on the underside of the second Peltier block in such a way as to come into contact with the portion of the test board.

Furthermore, the semiconductor package test device may further include a packing located between the Peltier chamber unit and the socket guides to seal the Peltier chamber unit and the socket guides.

Additionally, the semiconductor package test device using the Peltier elements may be configured to allow the top of the semiconductor package to have a temperature between −50 and 150° C. −and to allow the interior of the semiconductor package to have a temperature between −40 and 125° C.

### MODE FOR INVENTION

Hereinafter, an embodiment of the present invention will be described with reference to the accompanying drawings. If it is determined that the detailed explanation on the well-known technology related to the present invention makes the scope of the present invention not clear, the explanation will be avoided for the brevity of the description. In the description of the present invention, given numerical values are just defined in the embodiment of the present invention.

Hereinafter, an explanation of the present invention will be given in detail. Before the present invention is disclosed and described, it is to be understood that the disclosed embodiments are merely exemplary of the invention, which can be embodied in various forms. In the description, it should be noted that the parts corresponding to those of the drawings are indicated by corresponding reference numerals.

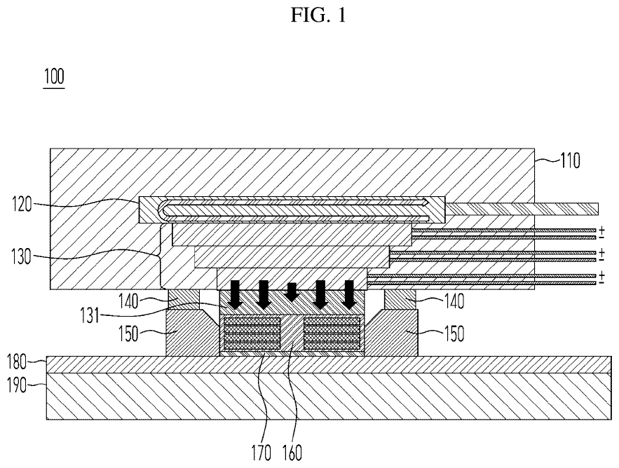

FIG. 1 is a schematic sectional view showing a conventional semiconductor package test device.

The conventional semiconductor package test device 100 includes a Peltier chamber unit 110 in which Peltier elements are located, socket guides 150 located on a test board 180 to guide a semiconductor package 160 so that the semiconductor package 160 is placed accurately in position, a pad part 170 located on the underside of the semiconductor package 160 and having electrical connectors for input and output of the semiconductor package 160 to determine whether the semiconductor package 160 generates the output with respect to the input accurately, and a test board 180 for placing the socket guides 150 and the pad part 170 thereon, and a SUS plate 281 located on the underside of the test board 280, made of stainless steel, and adapted to support the Peltier chamber unit 110, a water cooling jacket 120, a Peltier block 130, a packing 140, the socket guides 150, the semiconductor package 160, the pad part 170, and the test board 180 thereagainst.

The Peltier chamber unit 110 includes the water cooling jacket 120 located on the heat emission side of the Peltier block 130 constituted of one or more Peltier elements to cool the Peltier block 130, a thermoelectric block 131 whose one side is joined face to face to the Peltier block 130 and thus fixed to the Peltier chamber unit 110 and the other side comes into contact with the semiconductor package 160 as a test target to allow heat transfer between the Peltier block 130 and the semiconductor package 160, and the packing 140 located between the Peltier chamber unit 110 and the socket guides 150 to seal the Peltier chamber unit 110 and the socket guides 150 when the thermoelectric block 131 comes into contact with the semiconductor package 160.

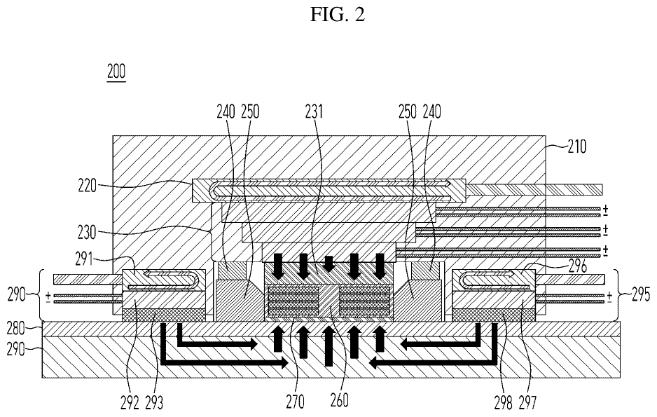

FIG. 2 is a schematic sectional view showing a semiconductor package test device using Peltier elements according to an embodiment of the present invention.

The semiconductor package test device 200 includes a Peltier chamber unit 210 in which Peltier elements are located, socket guides 250 located on top of a test board 280 to guide a semiconductor package 260 so that the semiconductor package 260 is placed accurately in position, a pad part 270 located on the underside of the semiconductor package 260 and having electrical connectors for input and output of the semiconductor package 260 to determine whether the semiconductor package 260 generates the output with respect to the input accurately, the test board 280 for placing the socket guides 250 and the pad part 270 thereon, and a SUS plate 281 located on the underside of the test board 280, made of stainless steel, and adapted to support the Peltier chamber unit 210, a first water cooling jacket 220, a first Peltier block 230, a packing 240, the socket guides 250, the semiconductor package 260, the pad part 270, and the test board 280 thereagainst.

The Peltier chamber unit 210 includes the first water cooling jacket 220 located on the heat emission side of the first Peltier block 230 constituted of one or more Peltier elements to cool the first Peltier block 230, a thermoelectric block 231 whose one side is joined face to face to the first Peltier block 230 and thus fixed to the Peltier chamber unit 210 and the other side comes into contact with the semiconductor package 260 as a test target to allow heat transfer between the first Peltier block 230 and the semiconductor package 260, the packing 240 located between the Peltier chamber unit 210 and the socket guides 250 to seal the Peltier chamber unit 210 and the socket guides 250 when the thermoelectric block 231 comes into contact with the semiconductor package 260, a first temperature compensation module 290 fixed to one side thereof in such a way as to be isolated from the outside of the socket guides 250 and thus come into contact with one side of the test board 280 when the semiconductor package 260 is pressed against the thermoelectric block 231, and a second temperature compensation module 295 fixed to the other side thereof in such a way as to be isolated from the outside of the socket guides 250 and thus come into contact with the other side of the test board 280 when the semiconductor package 260 is pressed against the thermoelectric block 231.

According to the embodiment of the present invention, the semiconductor package 260 is loaded in the Peltier chamber unit, and after the first Peltier block 230 in the Peltier chamber unit is changed to a temperature between −50 and 150° C., an electric current is applied to the semiconductor package 260. As a result, the internal temperature of the semiconductor package 260 is kept to a temperature between −40 and 125° C., which has no big deviation from outside temperature, conventional practice.

The electric current is applied when the electrical connectors (not shown) of the pad part 270 are joined to the input and output terminals of the semiconductor package 260, and the input and output terminals of the semiconductor package 260 have the shapes of balls. The electrical connectors are concavely formed on the pad part 270 in such a way as to insert the balls thereinto. In this case, the thermoelectric block 231 is joined to the semiconductor package 260 in such a way as to be pressed face to face against top of the semiconductor package 260.

In this case, the first Peltier block 230 have one or more Peltier elements and thus makes use of the Peltier effect to generate heat or cool air. The Peltier effect is a thermoelectric phenomenon where heat is either absorbed or released at the junction of two different conductors when an electric current flows through them. This effect results in one junction cooling down while the other heats up.

As shown in FIG. 2, each Peltier element of the first Peltier block 230 is provided with a first electrode and a second electrode, and the electric current is applied to the first electrode and the second electrode through an external interface. Further, polarities applied to the first electrode and the second electrode are changed to allow heat or cool air to be emitted down (which is not shown).

As shown in FIG. 2, the lower portions of the respective Peltier elements cool down and the upper portions thereof heat up. As the Peltier elements are multi-stacked on top of one another, they make thermoelectric block 231 become colder. In this case, heat is generated from the upper portions of the Peltier elements to thus allow cooling water to be introduced into the first water cooling jacket 220, so that water cooling is performed with the cooling water to cause the heat to be emitted to the outside of the Peltier chamber unit 210.

The embodiment of the present invention wherein heat is emitted from the upper portions of the Peltier elements is shown in FIG. 2, but if the polarities of the first electrode and the second electrode of each Peltier element are changed, cool air is generated from the upper portions of the Peltier elements, whereas heat is generated from the lower portions of the Peltier elements and thus transferred to the semiconductor package 260 through the thermoelectric block 231. In this case, the cooling water existing in the first water cooling jacket 220 has a temperature higher than the upper portions of the Peltier elements, so that the cool air on the upper portions of the Peltier elements is emitted to the outside of the Peltier chamber unit 210.

Further, the socket guides 250 serve to fix the semiconductor package 260 loaded in the Peltier chamber unit 210 in position. At least two pairs of socket guides 250 are provided to guide four sides of the semiconductor package 260, while allowing the electrical connectors of the pad part 270 and the semiconductor package 260 to be accurately joined to each other.

Unlike the conventional technology, the semiconductor package test device using the Peltier elements according to the embodiment of the present invention further has the first temperature compensation module 290 and the second temperature compensation module 295 on both sides of the lower portion of the Peltier chamber unit 210.

The current advancement of information processing technology necessitates the development of higher-performance semiconductors, and therefore, current technologies are focusing on improving semiconductor performance by packaging semiconductors multi-layered on the same area. In the case of a memory semiconductor, further, multi-layering of NAND flash memories is a measure of the technical skills, and even in the case of a non-memory semiconductor, a FinFET or Gate-All-Around 3D semiconductor technology has been continuously studied and developed.

As an amount of data processed per one semiconductor package increases, at present, a more reliable performance test is needed, and such a reliability test for semiconductor packages takes up a large portion in semiconductor manufacturing post-processes.

An existing temperature test using the Peltier elements is performed in such a way as to heat or cool the semiconductor package by means of direct contacts of the Peltier elements with top of the semiconductor package and thus apply a limitation temperature to the semiconductor package, and in this case, a temperature difference between the top of the semiconductor package adjacent to the Peltier elements and the underside of the semiconductor package adjacent to the test board may occur. According to the embodiment of the present invention, to solve such a problem, the temperature compensation modules are provided to perform additional heating and cooling for the semiconductor package using the test board located on the underside of the semiconductor package, thereby minimizing a temperature difference between the upper and lower layers of the semiconductor package to improve the reliability in the temperature test.

According to the embodiment of the present invention, the first temperature compensation module 290 includes a second water cooling jacket 291 allowing cooling water to flow to the upper portion thereof, a second Peltier block 292 located on the underside of the second water cooling jacket 291 in such a way as to supply cool air to the test board 280 from the lower portion thereof when the cool air is supplied from the thermoelectric block 231 to the semiconductor package 260 and to supply heat to the test board 280 from the lower portion thereof contrarily when the heat is supplied from the thermoelectric block 231 to the semiconductor package 260, and a first heat transfer plate 293 located on the underside of the second Peltier block 292 in such a way as to come into contact with the test board 280 to allow the cool air or heat emitted from the second Peltier block 292 to the test board 280.

The first temperature compensation module 290 is fixed to one side of the Peltier chamber unit 210, and when the thermoelectric block 231 presses top of the semiconductor package 260 with given pressure to allow the electrical connectors of the pad part 270 to be connected to the underside of the semiconductor package 260, the first heat transfer plate 293 of the first temperature compensation module 290 is brought into contact with the test board 280.

As mentioned above, if the cool air is applied from the thermoelectric block 231 coupled to top of the semiconductor package 260 to the semiconductor package 260, the underside of the semiconductor package 260 has a higher temperature than the top thereof, and in this case, if the cool air is emitted even from the second Peltier block 292 of the first temperature compensation module 290 and thus transferred to the test board 280, the cool air is transferred to the underside of the semiconductor package 260 through the SUS plate 281, so that a temperature deviation between the top and underside of the semiconductor package 260 becomes reduced to enable a more reliable temperature test. In this case, heat is emitted from the upper portion of the second Peltier block 292, and accordingly, the cooling water is circulated in the second water cooling jacket 291 to allow the heat to be emitted to the outside of the Peltier chamber unit 210.

Contrarily, if heat is applied from the thermoelectric block 231 coupled to top of the semiconductor package 260 to the semiconductor package 260, the underside of the semiconductor package 260 has a lower temperature than the top thereof, and in this case, if heat is emitted even from the second Peltier block 292 of the first temperature compensation module 290 and thus transferred to the test board 280, the heat is transferred to the underside of the semiconductor package 260 through the SUS plate 281, so that a temperature deviation between the top and underside of the semiconductor package 260 becomes reduced to enable a more reliable temperature test. In this case, cool air is emitted from the upper portion of the second Peltier block 292, and accordingly, the cool air is transferred from the second water cooling jacket 291 to the outside of the Peltier chamber unit 210.

The first temperature compensation module 290 is fixed to one side of the lower portion of the Peltier chamber unit 210, and if the Peltier chamber unit 210 moves to be open and closed, the first temperature compensation module 290 moves together with the Peltier chamber unit 210.

According to the embodiment of the present invention, the second temperature compensation module 295 includes a third water cooling jacket 296 allowing cooling water to flow to the upper portion thereof, a third Peltier block 297 located on the underside of the third water cooling jacket 296 in such a way as to supply cool air to the test board 280 from the lower portion thereof when the cool air is supplied from the thermoelectric block 231 to the semiconductor package 260 and to supply heat to the test board 280 from the lower portion thereof contrarily when the heat is supplied from the thermoelectric block 231 to the semiconductor package 260, and a second heat transfer plate 298 located on the underside of the third Peltier block 297 in such a way as to come into contact with the test board 280 to allow the cool air or heat emitted from the third Peltier block 297 to the test board 280.

The second temperature compensation module 295 is fixed to the other side of the lower portion of the Peltier chamber unit 210, and when the thermoelectric block 231 presses top of the semiconductor package 260 with given pressure to allow the electrical connectors of the pad part 270 to be connected to the underside of the semiconductor package 260, the second heat transfer plate 298 of the second temperature compensation module 295 is brought into contact with the test board 280.

As mentioned above, if the cool air is applied from the thermoelectric block 231 coupled to top of the semiconductor package 260 to the semiconductor package 260, the underside of the semiconductor package 260 has a higher temperature than the top thereof, and in this case, if the cool air is emitted even from the third Peltier block 297 of the second temperature compensation module 295 and thus transferred to the test board 280, the cool air is transferred to the underside of the semiconductor package 260 through the SUS plate 281, so that a temperature deviation between the top and underside of the semiconductor package 260 becomes reduced to enable a more reliable temperature test. In this case, heat is emitted from the upper portion of the third Peltier block 297, and accordingly, the cooling water is circulated in the third water cooling jacket 296 to allow the heat to be emitted to the outside of the Peltier chamber unit 210.

Contrarily, if heat is applied from the thermoelectric block 231 coupled to top of the semiconductor package 260 to the semiconductor package 260, the underside of the semiconductor package 260 has a lower temperature than the top thereof, and in this case, if heat is emitted even from the third Peltier block 297 of the second temperature compensation module 295 and thus transferred to the test board 280, the heat is transferred to the underside of the semiconductor package 260 through the SUS plate 281, so that a temperature deviation between the top and underside of the semiconductor package 260 becomes reduced to enable a more reliable temperature test. In this case, cool air is emitted from the upper portion of the third Peltier block 297, and accordingly, the cool air is transferred from the third water cooling jacket 296 to the outside of the Peltier chamber unit 210.

The second Peltier block 292 and the third Peltier block 297 each have one or more Peltier elements and thus make use of the Peltier effect to generate heat or cool air. The Peltier effect is a thermoelectric phenomenon where heat is either absorbed or released at the junction of two different conductors when an electric current flows through them. This effect results in one junction cooling down while the other heats up.

As shown in FIG. 2, each Peltier element of the second Peltier block 292 and the third Peltier block 297 is provided with a first electrode and a second electrode, and the electric current is applied to the first electrode and the second electrode through an external interface. Further, polarities applied to the first electrode and the second electrode are changed to allow heat or cool air to be emitted down (which is not shown).

The second temperature compensation module 295 is fixed to the other side of the lower portion of the Peltier chamber unit 210, and if the Peltier chamber unit 210 moves to be open and closed, the second temperature compensation module 295 moves together with the Peltier chamber unit 210.

While the present invention been described with reference to the particular illustrative embodiments, it is not to be restricted by the embodiments but only by the appended claims. It is to be appreciated that those skilled in the art can change or modify the embodiments without departing from the scope and spirit of the present invention.

### INDUSTRIAL APPLICABILITY OF THE INVENTION

The present invention relates to the semiconductor package test device using the Peltier elements, and the device includes the Peltier chamber unit in which the thermoelectric block located on the underside of the first Peltier block constituted of the Peltier elements comes into contact with the top of the semiconductor package to change the temperature on the top of the semiconductor package, the socket guides located on the test board to guide the semiconductor package, and the pad part located on the test board and having electrical connectors coupled to the input and output terminals on the underside of the semiconductor package.

The Peltier chamber unit includes one or more temperature compensation modules located on one side and the other side of a lower portion thereof in such a way as to come into contact with a portion of the test board on the outsides of the socket guides, when the thermoelectric block is coupled with the semiconductor package, to change the temperature on the underside of the semiconductor package, and the first water cooling jacket located on top of the first Peltier block in such a way as to cool the first Peltier block.

1. A semiconductor package test device using Peltier elements, comprising:
a Peltier chamber unit in which a thermoelectric block located on the underside of a first Peltier block constituted of the Peltier elements comes into contact with top of a semiconductor package to change a temperature on the top of the semiconductor package;
socket guides located on a test board to guide the semiconductor package; and
a pad part located on the test board and having electrical connectors coupled to input and output terminals on the underside of the semiconductor package,
wherein the Peltier chamber unit comprises:
one or more temperature compensation modules located on one side and the other side of a lower portion thereof in such a way as to come into contact with a portion of the test board on the outsides of the socket guides, when the thermoelectric block is coupled with the semiconductor package, to change the temperature of the underside of the semiconductor package; and
a first water cooling jacket located on top of the first Peltier block in such a way as to cool the first Peltier block.

2. The semiconductor package test device according to claim 1, wherein the temperature compensation modules comprise:
a first temperature compensation module fixed to one side of the lower portion of the Peltier chamber unit; and
a second temperature compensation module fixed to the other side of the lower portion of the Peltier chamber unit, and
the first temperature compensation module and the second temperature compensation module are located on the outsides of the socket guides, when brought into contact with the test board.

3. The semiconductor package test device according to claim 2, wherein the first temperature compensation module comprises:
a second Peltier block for emitting cool air or heat to the portion of the test board;
a second water cooling jacket located on top of the second Peltier block to cool the second Peltier block; and
a first heat transfer plate located on the underside of the second Peltier block in such a way as to come into contact with the portion of the test board.

4. The semiconductor package test device according to claim 1, further comprising a packing located between the Peltier chamber unit and the socket guides to seal the Peltier chamber unit and the socket guides.

5. The semiconductor package test device according to claim 2, wherein the second temperature compensation module comprises:
a third Peltier block for emitting cool air or heat to the portion of the test board;
a third water cooling jacket located on top of the third Peltier block to cool the third Peltier block; and
a second heat transfer plate located on the underside of the third Peltier block in such a way as to come into contact with the portion of the test board.
